(19) United States
(12) Patent Application Publication
(10) Pub. No.: US 2003/0115402 A1
(43) Pub. Date: Jun. 19, 2003

(54) Multiprocessor system

(76) Inventors: Fredrik Dahlgren, Lund (SE); Per Stenstrom, Torslanda (SE); Magnus Ekman, Goteborg (SE)

Correspondence Address: Burns, Doane, Swecker & Mathis, L.L.P., P.O. Box 1404, Alexandria, VA, 22313-1404, US

(21) Appl. No.: 10/295,433

(22) Filed: Nov. 15, 2002

Related U.S. Application Data
(60) Provisional application No. 60/332,592, filed on Nov. 23, 2001.

(30) Foreign Application Priority Data
Nov. 16, 2001 (SE) 0103847-0

(51) Int. Cl. G06F 12/00; G11C 5/00

(52) U.S. Cl. 711/1

(57) ABSTRACT

A multiprocessor system is described including a plurality of processors. At least one level of cache memory is operatively connected to each of the processors. At least one memory unit is shared by at least two of the processors. A status memory, in correspondence to each processor, is configured to store a current status in correspondence to memory regions capable of being stored in the cache memories. The current status indicates whether a memory region is non-shared. The system includes logic, in correspondence to and operatively connected to each processor, for generating minimum cache-coherence activities in response to a memory access request by a respective processor. The logic includes first cache-coherent minimizing logic that is configured to generate a direct memory access request for one of a next level of cache memory and the shared memory unit in response to a memory access request by the respective processor to a memory region causing a cache-miss and indicated as non-shared by the current status.

### RELATED APPLICATIONS

This application claims priority under 35 U.S.C. §119(e) to U.S. Provisional Application No. 60/332,592, filed Nov. 23, 2001, and claims priority under 35 U.S.C. §§119(a)-(d) and/or 365 to Swedish Application No. 0103847-0, filed Nov. 16, 2001, the entire contents of which are incorporated by reference.

### FIELD OF THE INVENTION

The present invention relates to a multiprocessor system comprising a plurality of processors, each having at least one level of cache memory operatively connected thereto, and at least one memory unit shared by at least two of said processors, and more particularly to a multiprocessor system comprising a logic in correspondence to and operatively connected to each processor for generating minimum cache-coherence activities in response to a memory access request from its corresponding processor.

### DESCRIPTION OF THE PRIOR ART

A system with more than one processor, and where the processors at least partially share the same memory is referred to as a multiprocessor. In the following description, the term processor can mean either a DSP or a CPU.

In systems with more than one processor, there are two basic principles. Either, the processors share the same address space, or they have completely separate address spaces. In the former case, it means that data that can be read from the memory from one processor can also be read from the same memory by another, a principle commonly known as shared-memory. Software is often composed of several program modules. When the software is run, program modules typically exchange information through a shared-memory. Consequently, if the program modules are executed on different processors in parallel, shared-memory is needed for correct execution.

A system can also have parts of the addressable memory as shared between two or more processors, and parts being unique to individual processors. In the following, we focus on memory accesses to the shared (part of the) memory.

While most multiprocessors have processors that are identical or similar, so called homogenous multiprocessors, a system with a CPU and a DSP that share memory is also referred to as a multiprocessor or a hetergenous multiprocessor. The term multiprocessor is used for both homogenous and heterogenous multiprocessors.

Mismatch between the maximum instruction execution speed of a processor and the access rate of memories can result in severe waiting times when a processor accesses the memory. Because of this, one or several cache memories that form a hierarchy is placed between the processor and the memory where one of them is closely coupled to the processor core. The cache memory closest to the processor is fast enough not to cause the processor to wait when it accesses the memory and the data or code is inside the cache memory. Cache memories are not part of the address space, so that data or code is placed there statically. Instead, the content of a cache memory is normally a function of the recent memory access by the processor. When the processor accesses data not currently in the cache, referred to as a cache miss, the data is fetched from a memory that has a longer access time, or latency, than the cache. That data is also copied into the cache. If the subsequent memory access is to the same data, that data is now contained in the cache, and consequently the access is very fast and does not cause the processor to wait. This is referred to as a cache hit. This technique is applied to all high-performance processors, and more and more of low-power embedded processors also use cache memories. Simple processors might have one cache memory for both code and data, while others have separate data and code caches meaning that the processor can fetch code and data in parallel without conflict. There are various organisations of caches, dictating how they behave in terms of data updates (write accesses), which data is replaced when new data is brought into the cache, etc.

In a multiprocessor where all processors have local cache memories, a problem referred to as the cache-coherence problem arises. Assume three processors in the system, P1, P2, and P3, each having a local data cache, C1, C2 and C3 respectively according to FIG. 2. From the start, C1, C2, and C3 are empty. P1 reads data D1, and since it is not contained in C1, it is read from memory, M. Now, D1 is inserted into C1. Assume the value of D1 is VA. If P2 now also reads D1, D1 will be copied into C2, and its value is still VA. Assume now that P2 writes a new value to D1, VB. This new value must be stored into C2 so that P2 reads the new value the next time it reads D1. However, since both the M and C1 currently have the old value of D1, VA, stored, the memory and caches are not coherent, i.e. a cache-coherence problem.

A number of mechanisms have been proposed for how to solve the cache-coherence scheme.

The most commonly used scheme is referred to as the write-invalidate protocol. When processor P2 updated D1, it sends out an invalidation-message to the memory and the other caches, and these marks the data invalid. As a result, only C2 contains D1, and as it gets the new value, the old value is nowhere to be found. D1 is marked Modified in C2. The advantage of this scheme is that if P2 subsequently updated D1 again, and D1 is still in C2 and marked Modified, this update can complete immediately locally, and no message needs to be sent out. Because of high memory reference locality in most software programs, this is a very common behavior making this cache-coherence scheme more effective than the one based on updates. The drawback of this scheme is that if P1 re-reads D1, it is no longer valid in its cache, and it has to fetch the data remotely from C2—a long-latency operation that would not have been necessary, had the cached copy been continuously updated with all processors' updates to D1. This kind of cache misses are referred to as coherence-misses, since they are caused by the cache-coherence scheme invalidating cache-blocks.

When a processor writes to data being shared, and is about to invalidate the copies residing in other caches, there are two basic principles. The first is called broadcast distribution, in which case the invalidation is sent out to all caches in the system. The alternative is to only send out invalidations to those caches that have a copy of the block, which we call selective distribution. In addition, if there is a cache miss at a read access, this read can either be broadcast to all caches, since the data might be Modified in one of the caches and there is no other valid copy of that data. Or, the read message can be selectively sent to the memory or one of the caches depending on where it can find the data valid. Observe that in the broadcast scheme, all global reads and invalidations from all processors reach each cache, requiring a lookup to see whether the message demands any action (invalidation of a copy, or for the cache to send a valid copy of the data in which case it becomes shared and is no longer marked as Modified). Also observe that in the selective scheme, there must be a mechanism that keeps track of which caches contain which data.

Traditionally, systems with up to some tens of processors are based on a single bus, to which all processors' caches are connected. Since each read and invalidation message put on the bus easily reaches all caches, a broadcast scheme is most often used. This bus-based, broadcast, write-invalidate protocol is considered the simplest, and is by far the most commonly used cache-coherence scheme. Such cache coherence protocols are also referred to as a snooping protocol, since the caches need to listen to—or snoop—on all messages that are sent on the bus. It is however limited by how fast a bus can operate when a large number of caches are attached to it, and the amount of message traffic caused by the caches. Therefore, larger systems use selective distribution, leading to a complex scheme for keeping track of which caches have copies of the data, and also keeps this information updated as data get evicted from caches in response to other data being fetched.

Almost all proposed cache-coherence mechanisms and apparatuses are proposed for high-performance systems, e.g. server systems, and for systems where each processor is a separate chip.

U.S. Pat. No. 6,038,644 discloses a multi processor system intended to solve the problem of increase of the cache miss latency due to large traffic on the shared bus used by the processors. For achieving this, a caching status memory is provided in correspondence to each of the processors. The caching status memory stores a status of each processor for discriminating whether each processor unit and each of the other processor units hold data which belongs to each of plural memory areas which belong to the shared memory. A logic is also provided in correspondence to each processor which responds to a memory access request from its processor and generates a first cache coherent processing request related to data of the memory address designated by the memory access request. Another logic is provided which generates information which designates destination processor unit of the cache coherent processing request. This destination information generate logic generates destination information designating part of the processor units which hold at least one data which belongs to the first memory area to which the first memory address belongs, based on the stored processor unit caching status. The multiprocessor system also includes an interconnection network for transmission of cache coherent processing requests. Still another logic is provided in correspondence to each processor for receiving notifications of the processor unit caching statuses from other processor units.

Thus, the system reduces the traffic for maintenance of cache coherency in the interconnection network, but the solution still cause a lot of cache-coherent activities causing power dissipation in the logic units in correspondence to each processor.

Recently, it became possible to put multiple processors on the same chip. This is either done for achieving and improving high-performance systems, or for obtaining systems with low power dissipation, in which case the processors either have not traditionally shared memory, have not had caches, or where the processor caches are not prepared for supporting cache-coherence (by e.g. handling invalidations coming from outside, supporting state-information needed by the cache-coherence protocol, etc.). There is an increased demand on high-performance by for example multimedia applications and multi-standard cellular communication scheme. Because of the high transistor densities making single CPUs and DSPs small in relation to the total chip area, having multiple processors on the chip is now a reality for ultra-low-power chips for use in e.g. third-generations phone terminals.

Because of the attractiveness of shared-memory, and because of the fact that most of the related processors have caches, there is an increased problem of power dissipation.

A prior art system Jetty—disclosed in JETTY: Filtering Snoops for Reduced Energy Consumption in SMP Servers. Proceedings of the 7th International Symposium on High-Performance Computer Architecture, January 2001, by A. Moshovos, G. Memik, B. Falsafi and A. Choudhary—for handling cache-coherence, is a small structure attached to each cache that try to filter snoop-broadcasts. Instead of doing a tag-lookup directly the Jetty is first checked. In many cases, the information in the Jetty can tell if it is any use to do the taq-lookup or not. Since the Jetty is much smaller than the cache, the Jetty-lookup is much cheaper than a tag-lookup in the cache and therefore energy is saved. Jetty was proposed to save energy in a system where the processors have private L1- and L2-caches. Since the Jetty there is used to filter tag-lookups in the L2-caches, which are big, the Jetty can still afford to consume a reasonable amount of energy.

The serial snooping technique—disclosed in C. Saldanha and M. Lipasti. Power Efficient Cache Coherence. Workshop on Memory Performance Issues, in conjunction with ISCA, June, 2001—is another prior art cache-coherence protocol based on the assumption that if a miss occurs in one cache, it is possible to find it in another cache without searching all of the other caches. If it is present in more than one of the other caches, the probability is high that the block will be found in a nearby cache. Even if the block is only present in one cache, it is still probable that the block will be found by just checking half of the caches. Instead of broadcasting the snoop-transaction to all of the processors in parallel, the processors are checked serially in a system based on serial snooping. This technique only works for snoops that are induced by a read miss, since it is sufficient to retrieve the block from one cache in these cases. On a write, an invalidation transaction needs to be broadcasted to all processors in the system and serial snooping cannot be used. In addition, the serial snooping scheme can cause substantial performance degradation at reads, if several caches are needed to be accessed, one at a time, until the requested block is found.

A traditional broadcast snooping protocol leads to a very high activity in the caches, since all read messages and invalidation messages lead to lookups in every cache. These look-ups are referred to as cache-coherence activities. This high activity in the caches is because messages from other processors can interfere with the local processor's own lookups in it, and normally enforces the cache to have parts of it duplicated (e.g. its state-information and register keeping track of which data are contained in it) so that external messages can be handled in parallel with the processor's own lookups. The selective distribution schemes proposed for high-performance multiprocessors with at least 16 processors are much too complex, increasing both design and verification time, and lead to higher power dissipation than a traditional bus-based snooping mechanism because of its directories or similar mechanisms needed to keep and maintain information about which data is where in the system. Although there are many improvements proposed for high-performance systems, that aim at reducing for example the number of messages sent over the network, these are more complex solutions that trade fewer messages for new directories or other activities. The end result might be slightly higher performance but to a higher complexity and higher power dissipation (which still might be a reasonable trade-off for a high-performance database server, for example).

Also programs run on one processor and that do not share data with other programs might also have to be subject to the cache-coherence protocol, because these programs might move its execution from one processor to another depending on the operating system's scheduling algorithm. An example of this can be that one processor is executing a large number of applications, while another is almost idle.

### SUMMARY OF THE INVENTION

It is an object of the present invention to provide a multiprocessor system which can reduce the power dissipation of logic in correspondence to the processors in the system.

This object is achieved by a multiprocessor system comprising a plurality of processors, each having at least one level of cache memory operatively connected thereto, and at least one memory unit shared by at least two of the processors, a logic in correspondence to and operatively connected to each processor for generating minimum cache-coherence activities in response to a memory access request from its corresponding processor. The multiprocessor system is characterised by a status memory provided in correspondence to each processor for storing a current status in correspondence to memory regions stored in the cache, wherein the current status indicates whether the memory region is non-shared, and by a cache-coherent minimising logic configured to generate a direct memory access request for the next level of cache memory or said shared memory unit in response to a memory access request to a memory region causing a cache-miss and indicated as non-shared by the status.

An advantage of the multiprocessor system according to the invention is that it consumes less power, since read and writes to those parts of the memory that are not currently shared do not lead to any unnecessary cache-coherence activities in other caches. Further, selectively distribute invalidations (or updates) are transmitted to only those caches that may have copies of the block.

The object is further achieved by a multiprocessor system characterised by a status memory provided in correspondence to each processor for storing a current status in correspondence to memory regions stored in the cache, wherein the current status indicates whether the memory region is currently read-only, and by a cache-coherent minimising logic configured to generate a read memory access request directly for the next level of cache memory or said shared memory unit in response to a read memory access request to a memory region causing a cache-miss and indicted as read-only by the current status.

Thus, reads to those parts of the memory that are known not being in state Modified in the cache of any processor do not lead to unnecessary cache-coherence activities in other caches.

A more specific object of the invention is to provide a multiprocessor system for reducing the power dissipation due to access misses to memory addresses not having a corresponding entry in the status memory.

This specific object of the invention is achieved by a multiprocessor system having cache-coherent minimising logic configured to detect whether a memory region is actively shared, wherein an actively shared memory region remains at or is decreased to a first size and a not actively shared memory region remains at or is increased to a second size essentially larger than the first size.

Another specific object of the invention is to provide a multiprocessor system for reducing the power dissipation due to cache-coherent requests, caused by memory access requests to a memory region not represented by the status memory.

This specific object of the invention is achieved by a multiprocessor system having a turn off mechanism configured to identify when the number of memory access requests to memory regions not represented by the status memory is considered high in relation to the cache-missrate according to a first algorithm, and to turn of said cache-coherent minimising logic for converting to a general cache-coherent logic.

### BRIEF DESCRIPTION OF THE DRAWINGS

In order to explain the invention in more detail and the advantages and features of the invention a preferred embodiment will be described in detail below, reference being made to the accompanying drawings, in which

FIG. 1 is a schematic block diagram of a chip-multiprocessor system according to the invention,

FIG. 2 is a schematic block diagram of the chip-multiprocessor system in FIG. 1 in further detail,

FIG. 3 is a schematic block diagram of a first embodiment of a page sharing table logic according to the invention, and

FIG. 4 is a schematic block diagram of a second embodiment of a page sharing table logic according to the invention.

### DETAILED DESCRIPTION OF THE INVENTION

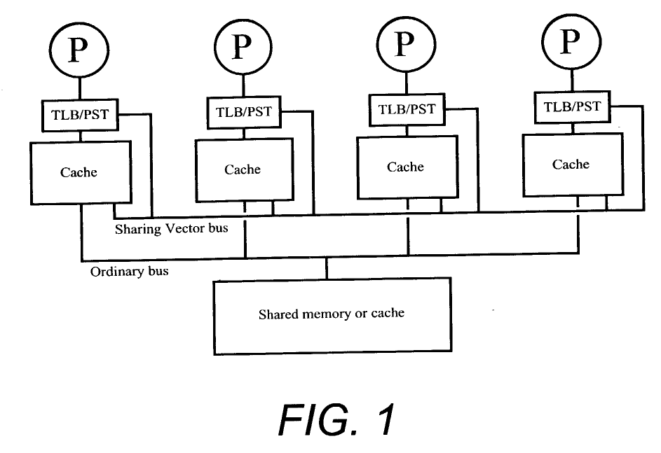

A multiprocessor system including logic for reducing the power dissipation in the system is shown in FIG. 1. The multiprocessor system comprises a plurality of processors (P), each having at least one level of cache memory operatively connected thereto, and at least one memory unit shared by the processors.

Further, the multiprocessor system has a mechanism or logic that keeps track of the sharing of memory regions, so that a decision can be taken locally at the processor-cache node, before a message (read or invalidation) is sent out to either the memory or other caches, whether coherence activities are needed. If the memory access is a read and the data or code is valid in the cache, the memory access is completed locally in the cache. If the memory access is a write, and the data is valid in the cache and in a state indicating that no other location in the system has the data valid, the write can also be completed locally in the cache. In other cases, the action taken depends whether the access is to a memory region that is shared or local, and whether it is to a region that is known not to be currently modified in one of the caches (referred to as read-only). If the access is to a non-shared memory region, no cache-coherence activities for the data is needed. If the access is a write and to a region marked as being shared, the activities are according to a traditional cache-coherence protocol, e.g. one known from prior art, but possibly only to those caches that might have copies of the block. Block refers to the size of the cache blocks in the data cache. If the access is a read, and to a region marked as read-only, the read should be sent to the next level of the memory hierarchy, which either is memory or the next level of cache that is shared between the processors, without any overhead for coherence actions. If the access is a code fetch (read of instructions), the read should be sent to the memory without any overhead for coherence actions.

Depending on whether the mechanism that keeps track of the sharing of memory regions also contains information of which caches that share a region, an access that must be according to a cache-coherence protocol can either be broadcast to all caches, or only interrogate those caches that are indicated as might share the memory region and therefore might contain the data.

The mechanism that keeps track of the sharing of memory regions allocates an entry of a memory region a memory address belonging to that region is accessed by the cache control unit and an entry for that memory region is not already allocated. It is required, that all cached data belongs to memory regions allocated. However, it is not required that all memory region entries have data belonging to them being cached (this can happen as blocks are being replaced or invalidated from the cache), since the logic and updating activities of status information for supporting that often consume more energy than is being saved by mechanisms utilizing it.

The result of the above principles and mechanisms is that only non-local reads and writes to actively shared memory regions are generating cache-coherence activities in other caches, as opposed to state-of-art and state-of-practice broadcast protocols, where all non-local reads and writes generate cache-coherence activities in all other caches. Non-local means that the access cannot correctly complete in the local cache.

Since cache coherence is typically maintained at the granularity of the size of a cache block and the size of a region can be larger, exact information about sharing can be lost. Another part of the invention therefore concerns an implementation of a mechanism that dynamically adjusts the size of a memory region with the goal of maintaining as exact information as possible about the sharing. In this embodiment, the size of a memory region could either be the same for all memory regions, or vary depending on what they contain, and whether the region is expected to be actively shared or not. For example, a program that always will execute on the same processor, and never will share any data with any other program, can have all its data in the same memory region. If the application uses a huge amount of data, a single memory region could correspond to a large portion of the memory. Another example is to let the memory regions be equal to the memory pages as defined by the operating system(s).

Assume a homogenous multiprocessor, based on a bus, and that the memory regions are equal to the page size used by the operating system. A baseline cache-coherence protocol used when cache-coherence enforcement is needed is a broadcast-based (snooping) write-invalidate protocol referred to as MESI or a modified MESI, where cached data can be in any one of the following states: Modified, Exclusive, Shared, or Invalid. This protocol is well known, but in the multiprocessor system according to the invention it is only used in situations where the relevant page is determined to be shared whereas in prior art the protocol is used for all pages.

In one embodiment of the invention, a Page Sharing Table technique (PST) is used, which is based on the intuition that there exist a fair number of pages that are not actively shared. Blocks in these pages are not subject to coherence. There also exist pages that are only actively shared among some processors, for example in producer-consumer behaviour (one processor updates data, that one other processor reads), where lookups could be avoided in the caches that do not participate in this behaviour. Actively shared, in this context, means shared data that is present in more than one private cache in the system.

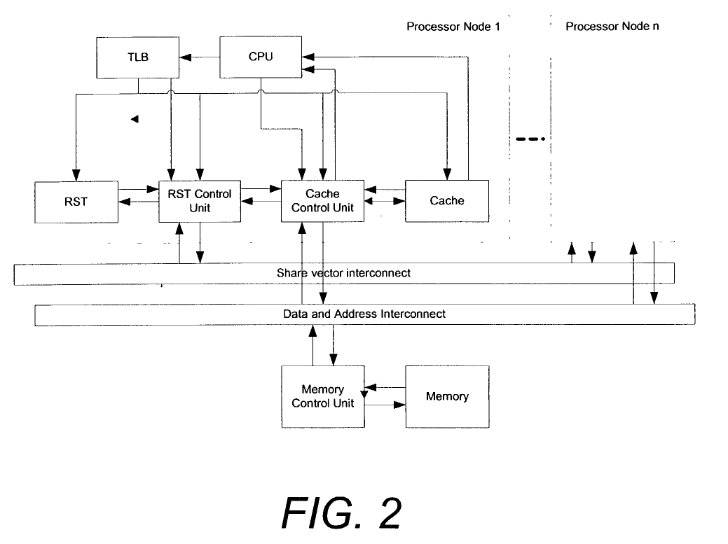

For avoiding snooping of blocks in pages that are not actively shared, a cache-coherent minimising logic or PST (Page Sharing Table) or RST (Region Sharing Table) is attached to each processor. The unit is tightly coupled to the TLB (Translation Lookaside Buffer) as indicated in FIGS. 1 and 2.

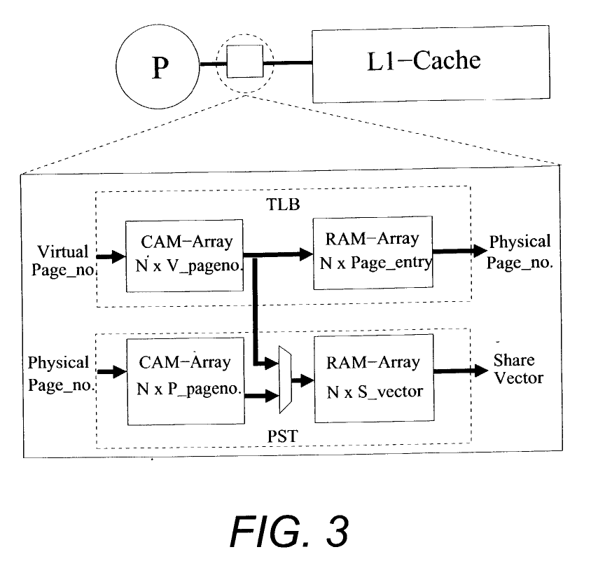

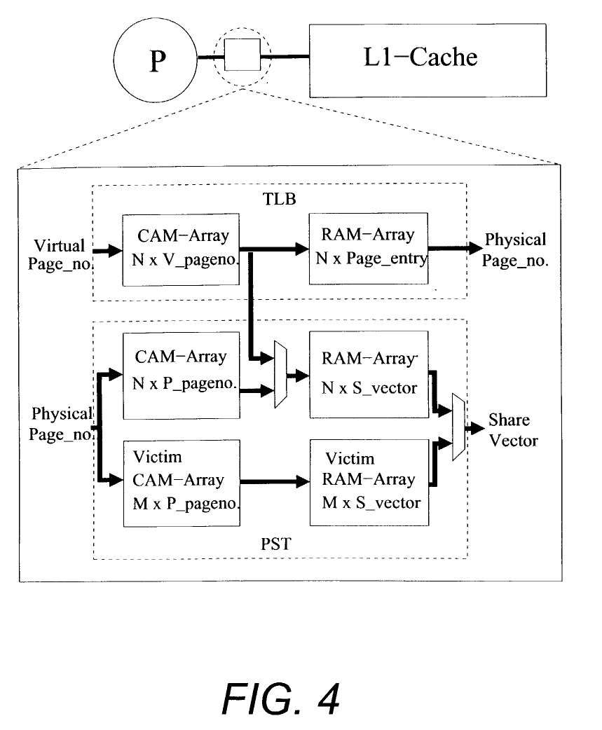

FIG. 3 shows a TLB with full associativity but the invention also works with a TLB with limited associativity. In that case the Content Addressable Memory (CAM) and the RAM is replaced by a cache-structure. For each entry in the TLB, a corresponding entry is kept in the RAM-Array in the upper right hand corner of the PST. In an alternative embodiment, shown in FIG. 4, of the first embodiment in FIG. 3 three other structures (two CAM-arrays and one RAM-array) are present to be able to keep the PST updated. The units called Victim CAM-Array and Victim RAM-Array are optional but if they are present, they contain entries that have been loaded in the upper units and later have been evicted.

Each entry in the PST contains a list of the processors that share that same page. We assume that there is inclusion between the PST and the L1-cache so that if a page-entry is not loaded in the PST, there will be no blocks belonging to that page loaded in the cache. The mechanism to assure this will be described later. The PST has to be accessed on cache misses and on writes to blocks in the states SHARED and OWNED. These are the same events that would lead to a snoop broadcast on the bus in a system without a PST. In all other cases the PST is not accessed, and therefore the critical path is not affected. The CAM-array stores the physical page-numbers for the entries loaded in the PST. By reading this array it is possible to locate a page-entry with the physical address, instead of the virtual which is used in the TLB.

It is possible that no data of a memory region is cached, even if there is a valid entry for that memory region in the PST. The reason for this solution is the avoidance of the overhead of maintaining such accuracy.

It is required that the PSTs in the system are coherent, meaning that if one PST indicates a certain memory region to be shared with a second node, the PST of that second not must have a valid entry for the memory region indicating the first node as sharing the region. This is maintained through specific PST update activities at PST entry allocations and PST entry replacements.

When a snoop action is broadcast on the bus in a system with a PST, it is accompanied by information about which processors that shall be affected by the snoop action. If a processor is not supposed to be affected, its snoop-controller does not have to do a cache lookup. An alternative approach is to use the information in the PST to decide if there shall be a snoop broadcast at all or if the L2-cache (Level 2 cache) shall be consulted directly. This makes a less complex implementation since information about which processors that shall be affected does not have to be transmitted. However, initial results show that this approach saves less energy.

Table 1 shows all the cases that cause a snoop broadcast and the action that should be taken in a system with PST as well as the action shat should be taken in the baseline system, depending on if the page is actively shared or not.

TABLE 1

| Cause of | | | |
|---|---|---|---|
| snoop | Shared | | Action in |
| broadcast | page | Action in PST-system | baseline-system |
| Read/ | Yes | Broadcast snoop action | Broadcast snoop action |
| Write miss | | to all of the | to all of the caches |
| | | caches that share | to try to retrieve |
| | | the page to try to | the data. If it does |
| | | retrieve the data | not exist, retrieve it |
| | | (Second approach: | from the next level of |
| | | Broadcast snoop | the memory hierarchy. |
| | | action to all of the | |
| | | caches). If it does not | |
| | | exist, retrieve it from | |
| | | the next level of the | |
| | | memory hierarchy. | |
| Read/ | No | Do not broadcast snoop | Broadcast snoop action |
| Write miss | | action. Retrieve data | to all of the caches |
| | | from the next level of | to try to retrieve |
| | | level of the memory | the data. If it does |
| | | hierarchy directly. | not exist, retrieve it |
| | | | from the next level of |
| | | | the memory hierarchy. |
| Write to | Yes | Broadcast snoop | Broadcast snoop action |
| block | | action to all | to all of the caches to |
| in state | | of the caches that | invalidate any present |
| SHARED or | | that share the page to | copy of the data. |
| OWNED | | invalidate any | |
| | | present copy of the | |
| | | data (Second approach: | |
| | | Broadcast snoop action | |
| | | to all of the caches). | |
| Write to | No | Write locally | Broadcast snoop action |
| block | | without accessing | to all of the caches |
| in state | | the bus. | to invaldidate |
| SHARED or | | | any present block. |
| OWNED | | | |

When a page-entry cannot be found in the TLB, it must be loaded and the information in the PSTs also must be updated. The page-entry is loaded from the page-table. The physical page-number is looked for in the PST by checking the two CAM-arrays. If the entry is present in the PST it is found in the victim array most of the times. The only time it can be found in the other arrays is after a context-switch when the TLB has been flushed. The entry is moved from the victim array to the upper structures in the place that corresponds to the place where the TLB-entry is loaded.

If the entry is not found in the PST, the processor must ask the other PSTs if they have the entry loaded. This is a transaction that is broadcasted on the bus and the processors that have the entry loaded answers by switching their pin on the bus that normally supplies the sharing vector. The other PSTs are also updated with the information that the entry now is loaded in the current PST. The entry that is replaced in the PST is moved to the victim arrays and throws out the entry that was placed there longest ago.

If this technique shall work, inclusion between the PST and the cache must be provided, so that when an entry is replaced in the PST, it is guaranteed that any block of that page is not present in the cache. The mechanism to guarantee inclusion, is simply to do a tag-lookup for each block that belongs to the page, and invalidate the blocks that are present. Since this is only done when an entry is thrown out from the PST which is less often than TLB-misses, which are extremely rare, the performance is not critical. However, it consumes energy. Simulation results indicate this not to be substantial.

The reason to have the replacements so tightly coupled to the TLB is that, then there is no need to check if the page-entry is loaded when a new cache block is read into the cache. We also get a good replacement policy (LRU based on every read), even though we do not access the PST on each read.

Each time that an entry is replaced in the PST, a search in the cache has to be performed to find blocks that have to be thrown out. Since this happens very seldom, it should not affect the performance. It consumes energy though, and this has been modeled by simulations, and early results indicate it not to be substantial. If blocks are evicted from the L1-cache it may lead to a higher miss-rate. Therefore it is necessary that the PST size is suited to the cache size so that blocks that will be used in the near future are not evicted. Simulations performed show that it is rather seldom that a block needs to be thrown out at all, since when a PST-entry is evicted its blocks have not been accessed for a long time and are often already replaced.

Read and writes to those parts of the memory that are not currently shared do not lead to any unnecessary cache-coherence activities in other caches. Selectively distribute invalidations (or updates) are transmitted to only those caches that may have copies of the block. In addition, reads to those parts of the memory that are not expected to be written to by any processor do not lead to unnecessary cache-coherence activities in other caches. An example of the latter is memory regions that are explicitly pointed out by software (program or system software) to be read-only. Another example is a mechanism that keeps track of whether any processor has written to a memory region recently. Furthermore, reads to memory in order to fetch code should not lead to any unnecessary cache-coherence activities in other caches in systems, software, or scenarios where self-modifying code is not being used.

The basic principle for providing sharing information on whether blocks loaded into the data cache is also present in other caches. This is by the use of a Region Sharing Table, RST. A region is a region of memory, e.g. a page, but can be smaller or larger. The size of a memory region is typically 2^{X} times the size of the cache blocks, where X is an integer number. Examples of memory region sizes include, but are not limited to, 4 kBytes, 16 kBytes, and 32 kBytes. In a particular case, a region is equivalent to a page, and a mechanism based on this is referred to as Page Sharing Table, PST.

In the basic principle, the memory regions can be all of the same sizes, they can be of different sizes but where their sizes are static throughout the execution, or the sizes are different and dynamically changing during the execution according to some algorithm.

The RST is a memory, where each entry corresponds to a memory region. Since the RST only keeps a limited number of entries, for example 16 or 32, each entry has a Tag indicating which address range it corresponds to. In addition, there is a Status field, indicating the status of the entry. Depending on the embodiment, example statuses are Invalid, Shared, and Non-shared, indicating whether the entry in the RST is invalid (meaning the entry is empty), or if its memory region might be shared by other nodes. There is also a Sharing Vector with one bit per other processing node in the system, indicating which nodes that might have any part of that memory region cached. Depending on embodiment, there might be other fields. The PST has similar fields.

There must be inclusion between the RST or PST and the data cache such that there cannot exist a valid block in the cache which does not belong to any of the memory regions having valid entries in the RST or PST.

It is possible that no data of a memory region is cached, even if there is a valid entry for that memory region in the RST or PST. The reason for this solution is the avoidance of the overhead of maintaining such accuracy.

It is required that the RSTs or PSTs in the system are coherent, meaning that if one RST or PST indicates a certain memory region to be shared with a second node, the RST or PST of that second not must have a valid entry for the memory region indicating the first node as sharing the region. This is maintained through specific RST or PST update activities at RST or PST entry allocations and RST or PST entry replacements.

One important aspect of the RST and PST according to the invention, is that the miss-rate of the RST or PST is critical. If the locality of accesses is bad, it can happen that a large number of memory regions are being accessed and only a few blocks are accessed per memory region. Then, the number of misses in the RST or PST is high, and each miss leads to an allocation of the corresponding entry and the replacement of another. At each replacement, the system must make sure the data cache does not have any of the memory regions' blocks valid. This can be a significant overhead and lead to an increase of the power dissipation instead of a decrease.

Therefore, part of the invention is to allow the RST to use large memory regions, larger than ordinary pages, and only when active sharing is detected is smaller memory regions used. Often, many of the memory regions will not be actively shared and therefore remain large, and the finite number of entries of the RST then corresponds to much larger physical address space. This leads to fewer replacements from the RST. This mechanism is referred to as dynamic resizing. Some embodiments of the invention, based on PST where each memory region has the size of the corresponding page (there could still be varying page sizes, but this is dictated by the operating system), cannot use dynamic resizing.

If the RST or PST is shown to have poor locality, even with dynamic resizing, a part of the invention is a method to dynamically de-activate the RST or PST, and to dynamically re-activate it when the locality is good. By this simple mechanism, even applications with extremely low locality can be handled without poor energy effectiveness, and the total solution becomes more stable. This method is referred to as dynamic activity control, and there are several possible implementations possible.

With further reference to the embodiment in FIG. 2. The memory is off-chip, while the memory controller is on-chip. Two different memory region sizes are supported by the region sharing table, 64 kByte (large) and 16 kByte (small). The mechanism is based on dynamic resizing, and the specific behavior is described below. Interconnect is a broadcast bus for data and address according to a cache-coherence protocol using four states; Modified, Exclusive, Shared, and Invalid, which is the fall-back strategy when cache-coherence is needed. However, the bus also supports multicast and updates of the RSTs through the Sharing Vector bus. Finally, the Small-Region interconnect with one bit per node, where each node can only set its corresponding bit but all nodes can read all bits. Each entry in the RST has, besides the Tag, Status, and Sharing-Vector fields, a 4-bit field Subregion (one bit per small region in a large region). The possible statuses of the Status field are Invalid, Non-shared-large, Non-shared-small, Shared-large, Shared-small.

RST Actions

There are a number of actions provided by the RST protocol.

Miss in RST by the Local Node:

Send RST-Request to all other nodes, with the address of the corresponding small region (16 kByte). They will look for the corresponding large region (by omitting the two least significant bits of the small region address) in their RST. If a node has either the large region allocated or at least one of small regions of that large region present in its RST, it will activate its bit in the Small-Region Interconnect. If a node has either an entry for the large region or the specific small region requested, it will set its bit in the Sharing Vector bus. (A node can therefore activare its bit in Small-Region but not in Sharing Vector, if it does not have the specific small region requested, but at least one of the other small regions belonging to the same large region.)

If a responding node has the small region entry in its RST, it updates the Sharing Vector with the requesting node's bit set to one, and if Non-Shared update the status field to Shared.

If a responding node has a large region entry in its RST, and has only one bit set in its Subregion field, it changes the entry to a small region entry for that corresponding small region. If that small region is the same as the requested small region, it updates the Sharing Vector and Status fields, and if not the fields remain unchanged.

If a responding node has a large region entry in its RST, and more than one bit set, it will keep the entry as a large region entry, add the requesting node to the Sharing Vector and make sure the Status field is Shared.

If no node activates its bit in the Small-Region interconnect, the requesting node will allocate its entry in its RST as a large region, Non-shared, and will mark the bit of the corresponding small region in its Subregion.

If any node activates its bit in the Small-Region interconnect, the requesting node will allocate its entry in its RST as a small region. Then, the Sharing Vector of that entry will be the result of the Sharing-Vector bus, and if there is at least one other node sharing the small region, the status of the entry will be Shared, otherwise non-shared.

Hit in the RST, to a Large Region Entry:

If the bit in the Subregion field for the corresponding small region is one, no further action in the RST.

If the bit in the Subregion field for the corresponding small region is zero, and the Status is Shared, then update it to one and send and RST-Update for the small region to those nodes indicated in the Sharing Vector of the entry. These nodes then check in their RST whether they have the small region present in their RST, and if so, they respond by setting their bit in the Small-region interconnect. They also update the Sharing Vector with the requesting node, the corresponding bit set to one, and if a node had the small region as Non-shared, it changes it to Shared.

If the bit in the Subregion field for the corresponding small region is zero, and the Status is Non-shared, update the Subregion bit.

Hit in the RST, to a Small Region Entry:

No RST update.

Replacement from RST:

All cached blocks in the data cache belonging to the region of the replaced RST entry (large or small) must be invalidated, and if the blocks are in state Modified they will have to be written back to memory (or a shared level-2 cache).

The RST could be direct-mapped, set-associative or fully associative. For this example embodiment, assume 4-way set-associative with an LRU replacement policy.

Cache Actions:

The following is the cache actions and related cache coherence actions.

Read hit in local cache: Status can be Exclusive, Shared or Modified. Read out data, no coherence actions.

Read miss in local cache: Check RST for corresponding large or small region entry. If RST needs update, those actions are prior to the handling of the cache block.

If the region (large or small) is Non-shared, send ns-read-request (non-shared read) to memory, which will return data, with e-data-transfer on the bus. Set cache-status to Exclusive.

If the region is Shared, a read-request is sent to the memory as well as multicast according to the Sharing Vector of the RST, where the the nodes which are marked in the Sharing Vector field in the RST are also marked on the Sharing Vector Bus. The receiver logic of the cache control unit in each node is such that only if its corresponding bit on the Sharing Vector Bus is set will the node react on caoherence requests. If any of the nodes has the block valid (in state Shared, Modified or Exclusive), that node will respond with a data-transfer, and the block will be in state Shared in all caches having a copy. The send logic of the cache control unit is such that if the local node is about to respond with a data-transfer, but another node is prior to put a data-transfer on the bus as a response to the same read-request, the local node will drop its data-transfer. As a result, only one data-transfer response will be sent to the requesting node, even if several nodes had the block in state Shared. If no cache responds, the memory will send a copy with a e-data transfer, which will then be in state Exclusive. (There is a small delay in this case, since the memory controller must first make sure no cache will send the data before the transfer is sent to the external memory. This additional delay is not present at a ns-read-request, since no other node will then have the block. However, off-chip memory is so much slower than the on-chip memory, and leads to higher power dissipation, so this is overall a good tradeoff.)

Write to block in state Modified: Write is completed in local cache, and no state update needed.

Write to block in state Exclusive: Write is completed in local cache, cache-block status updated to Modified.

Write to block in state Shared: Cache block is shared. Send invalidation-request on the bus. At the same time, the invalidation request activates the bus, the cache-block status is set to Modified.

Write to block not present in the cache: Check RST for corresponding large or small region entry. If RST needs update, those actions are prior to the handling of the cache block.

If the region (large or small) is Non-shared, send ns-read-request (non-shared read) to memory, which will return data, with e-data-transfer on the bus. Update the cahce block with the new value, and set cache-status to Modified.

If the region is Shared, an write-request is sent to the memory as well as multicast according to the Sharing Vector of the RST, where the the nodes which are marked in the Sharing Vector field in the RST are also marked on the Sharing Vector Bus. If any of the nodes has the block valid (in state Shared, Modified or Exclusive), that node will respond with a e-data-transfer, and the block will be invalidated to state Invalid in all caches having a copy. If no cache responds, the memory will send a copy with an e-data transfer. The requesting node will load the data into the cache, update the value according to its write, and set the state to Modified.

Replacement from cache: If the cache block is in state Modified, it must be written back to memory. If in any other state, no action is needed.

The cache can be organized as direct-mapped, or with an associativity, and the replacement algorithm for a set-associativity could be any. Those parameters are independent of above descriptions. For the example embodiment, assume 4-way set-associative, with an LRU replacement policy.

Dynamic Activity Control:

The embodiment also has dynamic activity control that relates the number of misses in the RST with that of the data cache according to the following algorithm. The is a counter of 8 bits, that never wraps around (meaning 255+1=255, 0-1=0). On each miss in the RST, the counter is added with 4. On each miss in the cache, the counter is decremented by one. As the counter reaches 100, the RST is inactivated.

When the RST is deactivated, the node treats all memory regions as potentially shared and the cache-coherence scheme behaves as when the RST indicate a Shared region with all nodes sharing the region. This, the cache-coherence requests are sent to all nodes (broadcast).

When the RST is deactivated, its Tag and Status fields are still being updated in order to measure whether the RST miss-rate is high or low. Since it does not update the sub-region filed or sharing vector field, and generate no RST activities over the network to other RSTs, it pessimistically treats all regions as small regions. Each RST miss now increases the counter with 8, and each cache miss decrements the counter with one. When the counter reaches zero, the RST is deactivated. Each RST entry now accessed will lead to RST-updates being sent over the interconnect-to-check for the sharing of large or small regions, and for updating the sharing vector, similar to the behavior of an RST miss. (However, the counter is not increased if the Tag for the region is already in the RST, in order to avoid oscillation of the activity control scheme.)

In a second embodiment, the memory is on-chip in a number of memory banks rather than off-chip, but the general principle of the solution is the same as in the first embodiment with the below specified differences. Since the memory is on-chip, and split into a number of smaller banks, it is less energy consuming to make a memory access than in the above embodiment.

The RST entries in this embodiment has an additional bit in the status field—Read-Only. If the Read-Only bit is not set, at least one of the nodes has written to any of the cache blocks belonging to the memory region. If the Read-Only bit is set, it means that no node has written to any of the blocks belonging to the memory region, since they allocated the RST entries. (A region can have the Read-Only bit being set even if there has been previous writes to the region, if all the RST entries have been replaced since the last write.)

At a load-request from a processor that misses in the cache, and where the RST entries indicate the region to be Shared but Read-Only, it is known that no other cache can have the block in state Modified, and the request is sent directly to the memory by a ns-read-request. By this, lookups in the other caches indicated by the Sharing Vector are prevented, which could all have been unsuccessful.

It is required that all RSTs are coherent with respect to the Read-Only bit, which is guaranteed as follows. At the allocation of an RST entry, when all RSTs are interrogated with respect to the memory region, the Read-Only bit is also communicated (same for all of them). If the memory region is not shared by any other node, it is preset to one if the RST-allocation is generated by a local read and present to zero if generated by a local write. If the bit has been set to zero, it will never change to one during its lifetime in the RST. If the Read-Only-bit is one, and another node experience a read-miss to the region, also that node will allocated an RST entry with the Read-Only-bit set to one. If the RST-entry is Shared and Read-Only (multiple nodes have an entry for the region with this status) and if one of the nodes writes to the region, the local RST will set its Read-Only-bit if the entry to zero, and since the region is shared an invalidation-notRO-request (indicating the region is no longer read-only) will be sent to the other nodes sharing the region. As these nodes receives the invalidation-notRO-request, they update their RST-entry by setting the Read-Only-bit to zero.

By this scheme, code regions as well as regions of shared data that is commonly read-only, such as language databases in the case of a multi-language man-machine-interface, or grammar and vocabulary in the case of a speech-recognition program, will cause a minimum of unnecessary cache-coherence overhead causing unnecessary energy consumption, even if the data is being shared.

In a third embodiment, similar to the second embodiment, only one regions size is used, 4 kBytes. Thus, there is no Subregion field in the RST entries. The changes of the RST mechanisms because of this should be clear to anyone skilled in the art.

It should be apparent that the present invention provides an improved multiprocessor system system for lower power-dissipation, that fully satisfies the aims and advantages set forth above.

The number of activities in other caches because of cache-coherence enforcements are drastically reduced, also for applications that have been parallelized so that the major work is done in parallel on multiple processors simultaneously. For non-parallel programs, unnecessary coherence-activities on other caches are almost eliminated which results in lower power-dissipation. In addition, it might make it realistic to, have simpler caches without duplication of the information about which data is contained in the cache and in what state it exist, without a significant performance penalty. The reason is that the probability that the processor's accesses conflict with coherence-related activities in the cache is dramatically reduced.

Although the invention has been described in conjunction with specific embodiments thereof, this invention is susceptible of embodiments in different forms, with the understanding that the present disclosure is to be considered as an exemplification of the principles of the invention and is not intended to limit the invention to the specific embodiments illustrated.

1. A multiprocessor system, comprising:
a plurality of processors, each having at least one level of cache memory operatively connected thereto;
at least one memory unit shared by at least two of the processors;
a status memory, in correspondence to each processor, configured to store a current status in correspondence to memory regions capable of being stored in the cache memories, wherein the current status indicates whether a memory region is non-shared; and
logic, in correspondence to and operatively connected to each processor, for generating minimum cache-coherence activities in response to a memory access request by a respective processor, the logic including first cache-coherent minimizing logic configured to generate a direct memory access request for one of a next level of cache memory and the shared memory unit in response to a memory access request by the respective processor to a memory region causing a cache-miss and indicated as non-shared by the current status.

2 The multiprocessor system according to claim 1, wherein the current status further indicates whether the memory region is currently read-only, the logic for generating minimum cache-coherence activities comprising:
a second cache-coherent minimizing logic configured to generate a read memory access request directly for one of the next level of cache memory and the shared memory unit in response to a read memory access request by the respective processor to a memory region causing a cache-miss and indicted as read-only by the current status

3. The multiprocessor system according to claim 1, wherein the logic for generating minimum cache-coherence activities comprises:
a third cache-coherent minimizing logic configured to generate a read memory access request directly for one of the next level of cache memory and the shared memory unit in response to a code-fetch memory access request by the respective processor.

4. The multiprocessor system according to claim 1, wherein the current status identifies at least one cache memory capable of holding data of the requested memory region.

5. The multiprocessor system according to claim 4, wherein the logic for generating minimum cache-coherence activities comprises:
a fourth cache-coherent logic configured to generate a cache-coherent processing request for the respective processor related to an address to the data of the requested memory region when the data is indicated as being held by the cache memories of other processors.

6. The multiprocessor system according to claim 5, wherein the fourth cache-coherent logic is further configured to generate the cache-coherent processing request only for the at least one cache memory capable of holding the data.

7. The multiprocessor system according to claim 1, comprising:
logic configured to identify when a number of memory access requests to memory regions not represented by the status memory exceeds a cache-miss rate according to a first algorithm; and
logic to configured to disable the logic for generating minimum cache-coherence activities when the number of memory access requests to memory regions not represented by the status memory exceeds the cache-miss rate.

8. The multiprocessor system according to claim 7, wherein the logic for generating minimum cache-coherence activities connected to the respective processor is disabled based on the first algorithm and the cache-miss rate of the cache memory connected to the respective processor.

9. The multiprocessor system according to claim 7, comprising:
logic configured to enable the logic for generating minimum cache-coherence activities when an estimation of the difference of the number of memory access requests to memory regions not represented by the status memory and the cache-miss rate reaches a second value.

10. A multiprocessor system comprising:
a plurality of processors, each having at least one level of cache memory operatively connected thereto;
at least one memory unit shared by at least two of the processors;
a status memory, provided in correspondence to each processor, for storing a current status in correspondence to memory regions capable of being stored in the cache memories, wherein the current status indicates whether the memory region is currently read-only; and
logic, in correspondence to and operatively connected to each processor, for generating minimum cache-coherence activities in response to a memory access request by a respective processor, the logic including first cache coherent minimizing logic configured to generate a read memory access request directly for one of the next level of cache memory and the shared memory unit in response to a read memory access request by the respective processor to a memory region causing a cache-miss and indicted as read-only by the current status.

11. The multiprocessor system according to claim 10, wherein the logic for generating minimum cache-coherence activities comprises:
logic configured to resize memory regions dynamically for usage by the multiprocessor system.

12. The multiprocessor system according to claim 11, wherein the logic configured to resize memory regions comprises:
logic configured to detect whether a memory region is actively shared;
logic configured to decrease the size of an actively shared memory region to a first size; and
logic configured to increase the size of a non-actively shared memory region to a second size larger than the first size.
